(19) United States
(12) Patent Application Publication
(10) Pub. No.: US 2021/0041270 A1
(43) Pub. Date: Feb. 11, 2021

(54) APPARATUS AND METHOD FOR CALIBRATING AN ANGLE SENSOR

(71) Applicant: Infineon Technologies AG, Neubiberg (DE)

(72) Inventor: Wolfgang GRANIG, Seeboden (AT)

(21) Appl. No.: 16/947,467

(22) Filed: Aug. 3, 2020

(30) Foreign Application Priority Data
Aug. 8, 2019 (DE) 102019121392.4

(51) Int. Cl. G01D 5/244; G01B 21/22

(52) U.S. Cl. CPC G01D 5/24452; G01B 21/22; G01D 5/2448

(57) ABSTRACT

An apparatus for calibrating an angle sensor is provided. The apparatus includes a data interface for capturing, for each of a plurality of different rotational angles of a test object, a first measurement value of a first sensor element as a function of a magnetic field at the location of the first sensor element, and a second measurement value of a second sensor element as a function of a magnetic field at the location of the second sensor element. The apparatus also including a processor for calculating a plurality of ellipse parameters of an ellipse equation based on the captured first and second measurement values, and calculating, based on the ellipse parameters, first characteristic data of a first periodic sensor signal, second characteristic data of a second periodic sensor signal, and a phase offset between the first and second periodic sensor signal.

### CROSS REFERENCE TO RELATED APPLICATION

This application claims priority to German Patent Application No. 102019121392.4 filed on Aug. 8, 2019, the content of which is incorporated by reference herein in its entirety.

### TECHNICAL FIELD

The present disclosure relates to angle sensors, for example, to the calibration of angle sensors.

BACKGROUND Rotation angle sensors for contactless capture of rotations are used in the automotive sector, for example. Rotation angle sensors can be realized using magnetic field sensors, for example, which are placed in the vicinity of a rotating test object such as a shaft. Here, a first measurement value (X) of a first sensor element can be determined as a function of a magnetic field at the location of the first sensor element, the magnetic field depending on a rotation angle α of the test object. Further, a second measurement value (Y) of a second sensor element can be determined as a function of a magnetic field at the location of the second sensor element, the magnetic field depending on the rotation angle α of the test object. In an ideal case, the two measurement values correspond to periodic signals of the form X=A*cos(α) and Y=A*sin(α). Then, using the known rule α=a tan(Y/X), it is possible to deduce the rotation angle α of the test object.

However, in practice, it is often not possible to entirely avoid mechanical misalignments between the sensor elements and test object, and so there are different amplitudes, offsets and phase shifts of the periodic signals X and Y, which in turn may lead to incorrect angle estimates. Causes for mechanical misalignments include x-, y-shift between sensor elements and test object or magnet, air gap variations (z-shift), various types of inclination (e.g., package or housing inclination) and/or magnetization inclination.

The application of an EoL (end-of-line) calibration was a previous solution of providing a sufficient error budget over an entire service life, including mechanical loads and the influences of temperature. Here, use is often made of so-called multipoint calibration methods, in which deviations of angle estimates by an angle sensor from a plurality of known reference angles (sampling points) are determined and saved, for example in a lookup table (LUT). This then subsequently allows correction values for the angle estimates to be ascertained. However, the provision of the reference angles is linked to additional hardware outlay, for example in the form of additional, highly precise optical measuring devices.

### SUMMARY

Compensating causes of angle errors in angle sensors by way of a calibration with less hardware outlay is achieved by the apparatuses and methods according to the independent claims. Advantageous developments are the subject matter of the dependent claims.

According to a first aspect of the present disclosure, a method for calibrating an angle sensor is proposed. Here, the following steps are carried out for each of a plurality of different rotational angles of a test object:
capturing a first measurement value of a first sensor element as a function of a magnetic field at the location of the first sensor element, the magnetic field depending on the rotational angle of the test object, and a second measurement value of a second sensor element as a function of a magnetic field at the location of the second sensor element, the magnetic field depending on the rotational angle of the test object,
ascertaining a plurality of ellipse parameters of an ellipse equation on the basis of the captured first and second measurement values, and
on the basis of the ascertained ellipse parameters:
   determining first characteristic data of a first periodic sensor signal of the first sensor element,
   determining second characteristic data of a second periodic sensor signal of the second sensor element, and
   determining a phase offset between the first and second periodic sensor signal.

According to a further aspect, an apparatus for calibrating an angle sensor is also proposed. The apparatus comprises a data interface which captures, for each of a plurality of different rotational angles of a test object, a first measurement value of a first sensor element as a function of a magnetic field at the location of the first sensor element, the magnetic field depending on the rotational angle of the test object, and a second measurement value of a second sensor element as a function of a magnetic field at the location of the second sensor element, the magnetic field depending on the rotational angle of the test object. Further, the apparatus comprises a processor, embodied to calculate a plurality of ellipse parameters of an ellipse equation on the basis of the captured first and second measurement values and, on the basis of the ascertained ellipse parameters, calculate first characteristic data of a first periodic sensor signal of the first sensor element, second characteristic data of a second periodic sensor signal of the second sensor element, and a phase offset between the first and second periodic sensor signal.

Thus, ellipse parameters can initially be ascertained during a calibration mode on the basis of measurement values at different rotational angles and, in turn on the basis thereof, it is possible to ascertain characteristic data of the first and second periodic sensor signals and a phase offset between the two sensor signals. According to some example implementations, the ascertained first and second characteristic data are then usable for correcting angles in a normal mode of operation of the angle sensor that follows the calibration mode.

So that the two measurement values ideally correspond to periodic signals in the form X=A*cos(α) and Y=A*sin(α), the first sensor element can be sensitive to a first directional component of the magnetic field (e.g., X-direction) and the second sensor element can be sensitive to a second directional component of the magnetic field (e.g., Y-direction) according to some example implementations, with the second directional component being perpendicular to the first directional component. Alternatively, the first and second sensor element can be sensitive to the same directional component of the magnetic field, with a 90° phase shift ideally being set between the first and second sensor signal by way of the location of the first and second sensor elements or a distance between the sensor elements. By way of example, the sensor elements can be magnetic field sensor elements in the form of magnetoresistive sensors or Hall sensors.

According to some example implementations, the first characteristic data comprise a first amplitude Aₓ and a first mean value or offset Oₓ of the first periodic sensor signal and the second characteristic data comprise a second amplitude A_{Y} and a second mean value or offset O_{Y} of the second periodic sensor signal. The two sensor signals can additionally be shifted by corresponding phase angles φx and φy.

X=A_{X}·cos(α+φ_{X})+O_{Y}

Y=A_{Y}·sin(α+φ_{Y})+O_{Y}

According to some example implementations, the different rotational angles, at which the first and second measurement values are captured, capture at least one 360° rotation of the test object. Thus, the test object can run through an entire 360° rotation during the calibration mode. If there are n different rotational angles where first and second measurement values are measured in each case, adjacent measurement rotational angles may be spaced apart by 360° /n, for example.

According to some example implementations, the plurality of the first and second measurement values are respectively captured simultaneously. The simultaneous capture ensures that the first and second measurement values are not captured at different rotational angles, which could lead to an incorrect calibration.

According to some example implementations, the ellipse parameters of the ellipse equation are ascertained on the basis of the method of least squares. Here, an ellipse running as close as possible to the data points is sought after in a data point cloud (in this case: the measurement values).

According to some example implementations, the ellipse equation has the following form:

ax²+bxy+cy²+dx+fy+g=0

The ellipse parameters a, b, c, d, f, g can be ascertained using the least squares error method using the equation C=(M^{T}M)⁻¹M^{T}Z, where

$$M = [ \begin{matrix}{X}_{0}^{2} & {X}_{0} {Y}_{0} & {Y}_{0}^{2} & {X}_{0} & {Y}_{0} \\ {X}_{1}^{2} & {X}_{1} {Y}_{1} & {Y}_{1}^{2} & {X}_{1} & {Y}_{1} \\ ⋮ & ⋮ & ⋮ & ⋮ & ⋮ \\ {X}_{n - 1}^{2} & {X}_{n - 1} {Y}_{- 1 n} & {Y}_{n - 1}^{2} & {X}_{n - 1} & {Y}_{n - 1}\end{matrix} ]$$

is a measurement value matrix on the basis of the plurality of first and second measurement values and Z=[1 1 . . . 1]^{T} is a possible target amplitude of the calibration and represents a negative value of the parameter g. In this case, the ellipse is mapped onto the unit circle. Auxiliary parameters, which can be used to ascertain the first characteristic data of the first periodic sensor signal and the second characteristic data of the second periodic sensor signal of the second sensor element and the phase offset between the first and second periodic sensor signal can be determined from the coefficients C₀ . . . Cₙ₋₁ and the unit circle amplitude, from which the ellipse parameters arise.

According to some example implementations, the ellipse equation is rewritten as x=f(y) for the purposes of determining the first amplitude A_{X} and the first mean value O_{X} of the first periodic sensor signal and the derivative is set to be dx/dy=0. Then, this can be used to obtain maximum and minimum x-values of the ellipse corresponding to the ascertained ellipse parameters. Accordingly the ellipse equation is rewritten as y=f(x) for the purposes of determining the second amplitude A_{Y} and the second mean value O_{Y} of the second periodic sensor signal and the derivative is set to be dy/dx=0. Then, this can be used to obtain maximum and minimum y-values of the ellipse corresponding to the ascertained ellipse parameters.

According to some example implementations, the first mean value O_{X} can be ascertained on the basis of an averaging of the maximum and minimum x-values of the ellipse corresponding to the ascertained ellipse parameters and the second mean value O_{Y} can be ascertained on the basis of an averaging of the maximum and minimum y-values of the ellipse.

According to some example implementations, the first amplitude A_{X} can be ascertained on the basis of the maximum (or minimum) x-value of the ellipse and the first mean value O_{X} and the second amplitude A_{Y} can be ascertained on the basis of the maximum (or minimum) y-value of the ellipse and the second mean value O_{Y}.

According to some example implementations, the phase offset cp between the first and second periodic sensor signal can be ascertained as per

$$ϕ = - asin ( \frac{{y}_{A x} - {O}_{Y}}{{A}_{Y}} )$$

where y_{Ax}, denotes a y-value of the ellipse in the case of the maximum x-value of the ellipse, O_{Y} denotes the mean value of the second sensor signal, and A_{Y} denotes the amplitude of the second sensor signal.

Example implementations of the present disclosure thus propose the use of an ellipse fitting function, which uses randomly distributed, corresponding component values for X and Y. No angle reference is required to this end.

### BRIEF DESCRIPTION OF THE FIGURES

A few examples of apparatuses and/or methods are explained in more detail below merely by way of example with reference to the appended figures. In the figures:

FIG. 1 shows a schematic illustration of a magnetic field sensor;

FIG. 2 shows a measuring circle;

FIG. 3 shows an error-afflicted measuring circle;

FIG. 4 shows ideal sine and cosine signals in comparison with signals with amplitude, offset and phase deviations;

FIG. 5 shows an apparatus for calibrating an angle sensor according to one example implementation; and

FIG. 6 shows a method for calibrating an angle sensor according to one example implementation.

### DESCRIPTION

Various examples will now be described in more detail with reference to the appended figures, in which a number of examples are illustrated. In the figures, the thicknesses of lines, layers and/or regions may be exaggerated for clarification.

Further examples are suitable for different modifications and alternative forms, and consequently a few specific examples thereof are shown in the figures and will be described in detail below. However, this detailed description does not limit further examples to the described specific forms. Further examples may cover all modifications, correspondences and alternatives that fall within the scope of the disclosure. The same or similar reference signs relate throughout the description of the figures to the same or similar elements, which upon comparison with one another may be implemented identically or in a modified form, while providing the same or a similar function.

It is to be understood that where an element is referred to as being “connected” or “coupled” to another element, the elements may be connected or coupled directly or via one or more intermediate elements. When two elements A and B are combined using an “or”, this is to be understood to mean that all possible combinations are disclosed, e.g., only A, only B, and also A and B, unless explicitly or implicitly defined otherwise. An alternative wording for the same combinations is “at least one of A and B” or “A and/or B”. The same applies, mutatis mutandis, to combinations of more than two elements.

The terms used here to describe specific examples are not intended to be limiting for further examples. If a singular form, e.g. “a, an” and “the”, is used and the use only of a single element is defined as being neither explicitly nor implicitly binding, further examples may also use plural elements to implement the same function. When a function is described below as being implemented using a plurality of elements, further examples may implement the same function using a single element or a single processing entity. Furthermore, it is understood that the terms “comprises”, “comprising”, “has” and/or “having” when used concretize the presence of the indicated features, whole numbers, steps, operations, processes, elements, components and/or a group thereof, but do not exclude the presence or the addition of one or more further features, whole numbers, steps, operations, processes, elements, components and/or a group thereof.

Unless this is otherwise defined, all terms (including technical and scientific terms) are used here in their typical meaning in the field to which examples belong.

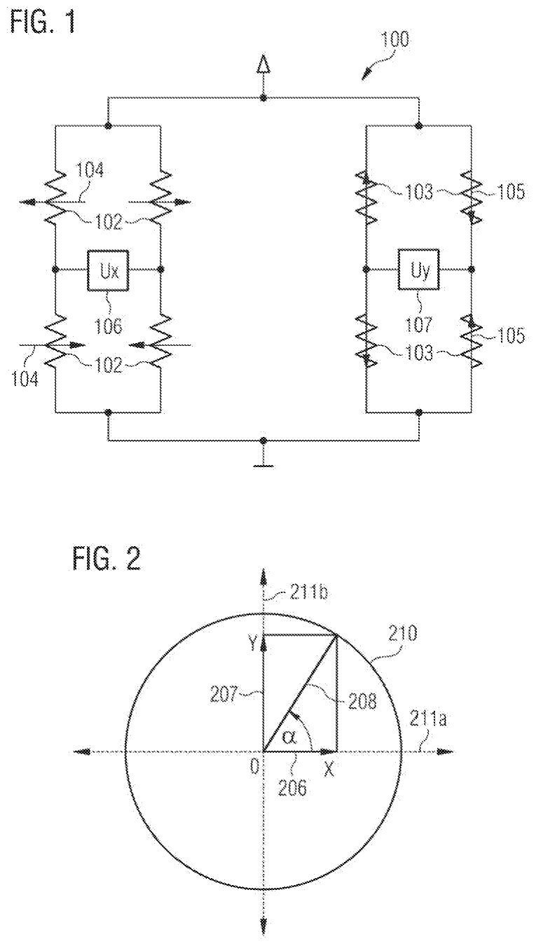

FIG. 1 shows a possible implementation of an angle sensor 100 in the form of a GMR (giant magnetoresistance) measuring bridge.

It will immediately be evident to a person skilled in the art that other configurations to the one shown in FIG. 1 can be used, by all means, as an angle sensor. By way of example, alternative sensors include AMR (anisotropic magnetoresistive) sensors, TMR (tunnel magnetoresistive) sensors or Hall sensors, to name but a few.

Rotation angle sensors on the basis of the GMR effects according to the spin valve principle can have advantages over AMR sensors. Thus, rotation angle sensors on the basis of the GMR effect can have an inherent 360° uniqueness if use is made of a bridge arrangement, and may have a higher sensitivity than AMR sensors. Therefore, the use of rotation angle sensors on the basis of the GMR effect can bring advantages both in terms of performance and in terms of costs. In order to realize a 360° detection using spin valve GMR/TMR structures, it is possible to interconnect a plurality of layer systems to form two Wheatstone bridges. This allows a maximum signal to be obtained. Here, one of the bridges has reference magnetizations, which are perpendicular to the reference magnetizations of the other bridge. The reference magnetizations are arranged in antiparallel within each of the two bridges. Consequently the two bridges supply sinusoidal main signals, depending on the rotation angle of an external magnetic field, which are (ideally) phase-shifted by 90° with respect to one another. Below, the two main signals are also referred to as main sine signal and main cosine signal.

The magnetic field sensor 100 in FIG. 1 has a first sensor elements 102, which are aligned with a first preferred direction 104, and second sensor elements 103, which are aligned with a second magnetic bias direction 105. Four first sensor elements 102 are interconnected to form a first bridge circuit. Likewise, four second sensor elements 103 are interconnected to form a second bridge circuit. The first measuring bridge is embodied to capture a component of the first preferred direction 104 of a magnetic field and the second measuring bridge is embodied to capture a second component of the second preferred direction 104 of the magnetic field to be captured. The first measuring bridge is embodied to generate a first bridge voltage Ux 106, which corresponds to the first component of the magnetic field, specifically the component along the first magnetic bias direction or preferred direction. The second measuring bridge is embodied to generate a second bridge voltage U_{Y} 107, which corresponds to a second component, specifically the component of the magnetic field to be captured, along the second magnetic bias direction.

The principle of the rotation angle measurement is based on a two-dimensional coordinate system being sufficient to determine an angle. The measuring system supplies an X-value and a Y-value, related to an origin of the coordinate system, for example the voltages U_{X}, U_{Y}, shown in FIG. 1, of a measurement point. The associated angle α of the measurement point can be calculated from this XY-value pair using a microprocessor-suitable method. Now, if all measurement values U_{X}, U_{Y} are located on a circular path, the calculated angle accurately describes the absolute position of the rotation angle. By way of example, if a magnet is rotated over two magnetic sensors and if, e.g., one sensor is aligned along the X-axis and the second sensor is aligned along the Y-axis, the sine and cosine components of the circular movement are detected. The angle can be deduced by way of the arctangent function atan(Y/X). Since the angle specifies a direction of the measurement point in relation to the coordinate system, this application can be used as an angle sensor.

FIG. 2 elucidates the principle of the angle measurement. An X-component and a Y-component are plotted in a rectangular coordinate system. A first component 206 of a captured magnetic field direction 208, in this case the X-component, is plotted in the direction along a first axis, in this case the X-axis 211a. A second component 207 of the captured magnetic field direction 208, in this case the Y-component, is plotted in the direction along a second axis, in this case the Y-axis 211b. An angle α of the magnetic field direction 208 can be calculated from the captured X- and Y-components, captured, for example, by the magnetic field sensors shown in FIG. 1. That direction vector of the magnetic field direction 208 corresponds to a diagonal of a rectangle spanned by the X-component 206 and the Y-component 207. Consequently, the angle α of the magnetic field direction 208 can be calculated by an arctangent calculation from the X-component 206 and the Y-component 207.

However, if the measurement points no longer lie on a circular path but lie on an inclined, displaced elliptical path with non-orthogonal axes, there is a deviation between the calculated angle and the actual angle of a direction to be captured.

Deviations from the orthogonality between the two measuring bridge elements, differences in the measuring bridge sensitivities and different offset errors can lead to a deviation from the ideal circular path. The general trajectory is elliptical, has a displaced center, and has an inclined axis position. By way of example, the aforementioned influences may be dependent on aging and temperature.

Errors may likewise arise from manufacturing and assembling the angle sensor; these errors should be eliminated again in the application of the sensor element in order to ensure a correspondingly high measurement accuracy for the angle. Here, three error types may occur.

An offset error brings about an offset along the X- and/or Y-axis. An offset should be expected as a result of manufacture and temperatures during operation. This leads to a displacement of the measuring circle.

An amplitude error brings about an amplitude along the X- and/or Y-axis. An amplitude error should be expected as a result of manufacture and, especially, the temperature. This leads to the circle being distorted into an ellipse, the latter, however, still having the principal axes along the X- or Y-axis.

An angle error between the X- and Y-component arises if the sensors are not orthogonal or positioned at 90° or if the sensors are not accurately manufactured.

In summary, what can be stated is that the sum of occurring errors changes the circle to be presented into a general ellipse, which may be displaced from the origin at any angle.

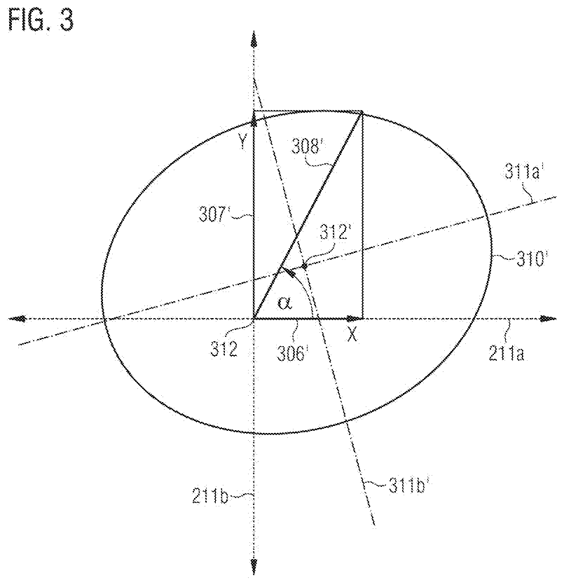

FIG. 3 shows a distortion of the circular path into an elliptical path as a result of influences. An error-afflicted X-component 306′ and an error-afflicted Y-component 307′ of the captured magnetic field direction vector 308′ span a vector diagram, from which an error-afflicted angle α′ of the captured magnetic field direction can be calculated. As a result of the error-afflicted X-component 306′ and the error-afflicted Y-component 307′, the direction vector 308′ does not describe a circle around the origin of the X-axis 211a and the Y-axis 211b; instead, it describes an ellipse 310′ about the center of an error-afflicted X-axis 311a′ and an error-afflicted Y-axis 311b′. An origin 312 of the circle coordinate system deviates from an origin 312′ of the ellipse coordinate system. Moreover, the axes of the ellipse coordinate system 311a′, 311b′ are rotated with respect to the circle axes 211a, 211b. Moreover, the error-afflicted ellipse axes 311a′, 311b′ could have an angle with respect to one another that deviates from 90°.

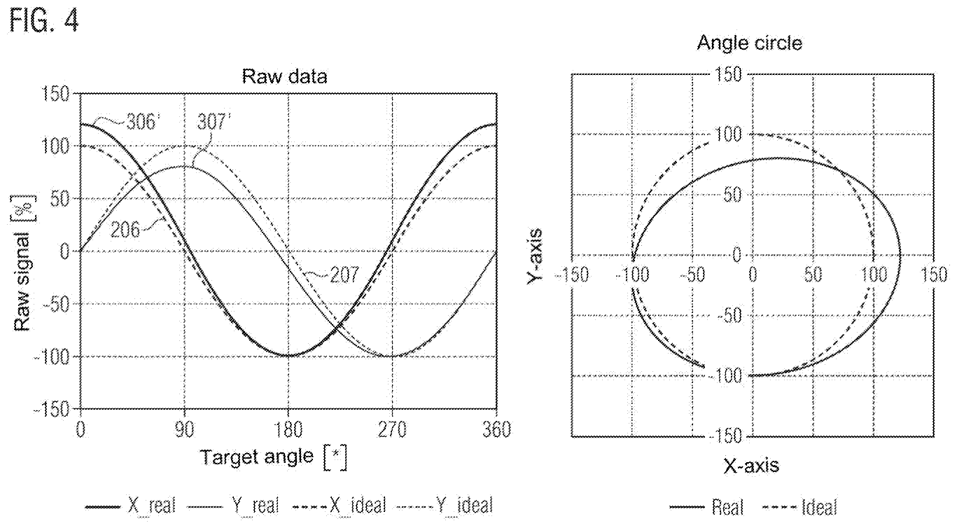

In addition to a circle 402 that has been distorted into an ellipse 404, FIG. 4 also shows the associated measurement values, plotted over an angular range of 0° to 360°, of the error-afflicted X- and Y-components 306′, 307′ in comparison with ideal X- and Y-components 206, 207.

The error-afflicted X- and Y-components 306′, 307′ can be modeled according to

X=A_{X}·cos(α+φ_{X})+O_{Y}

Y=A_{Y}·sin(α+φ_{Y})+O_{Y}

Here, A_{X} and A_{Y} denote the respective amplitudes, O_{X} and O_{Y} denote the respective offsets, and φ_{X} and φ_{Y} denote the respective phase shifts of the component signals X and Y.

The present disclosure then proposes apparatuses and methods, using which the aforementioned parameters A_{X}, A_{Y}, φ_{X}, φ_{X}, O_{X}, O_{Y} of the error-afflicted X- and Y-components can be estimated and used for correcting the angle.

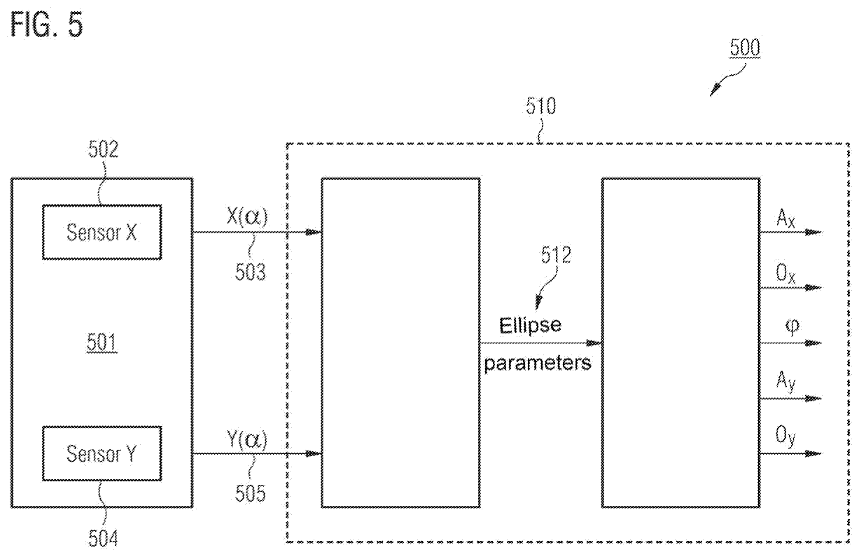

FIG. 5 schematically shows an apparatus 500 for calibrating an angle sensor 501 according to one example implementation.

The apparatus 500 comprises a data interface 503, 505 which, for each of a plurality of n different rotational angles αᵢ (i=0, . . . , n−1) of a test object (not shown), captures a first measurement value Xᵢ of a first sensor element 502 as a function of a magnetic field at the location of the first sensor element 502, the magnetic field depending on the rotational angle αᵢ of the test object. Further, for each of the plurality of different rotational angles αᵢ of the test object, the data interface captures a second measurement value Yᵢ of a second sensor element 504 as a function of a magnetic field at the location of the second sensor element 504, the magnetic field depending on the rotational angle ai of the test object. By way of example, the sensor elements 502, 504 can be bridge circuits of magnetoresistive sensor elements, similar to FIG. 1.

Further, the apparatus 500 comprises a processor 510, embodied to calculate a plurality of ellipse parameters 512 of an ellipse equation on the basis of the captured first and second measurement values Xᵢ, Yᵢ and, on the basis of the ascertained ellipse parameters 512, calculate first characteristic data 514-1 of a first error-afflicted periodic sensor signal X′ of the first sensor element 502, second characteristic data 514-2 of a second error-afflicted periodic sensor signal Y′ of the second sensor element 504, and a phase offset co between the first and second error-afflicted periodic sensor signal X′, Y′.

According to some example implementations, the ellipse equation has the quadratic form:

ax²+bxy+cy²+dx+fy+g=0

The ellipse parameters a, b, c, d, f, g, which best correspond to the measurement values Xᵢ, Yᵢ, can be ascertained using curve fitting, in particular using the least squares error method.

To this end, initially n sampled values of the component signals

Pᵢ=[Xᵢ, Yᵢ]i=0 . . . (n−1)

can be captured. These first and second measurement values Xᵢ, Yᵢ can be used to establish an observation matrix

$$M = [ \begin{matrix}{X}_{0}^{2} & {X}_{0} {Y}_{0} & {Y}_{0}^{2} & {X}_{0} & {Y}_{0} \\ {X}_{1}^{2} & {X}_{1} {Y}_{1} & {Y}_{1}^{2} & {X}_{1} & {Y}_{1} \\ ⋮ & ⋮ & ⋮ & ⋮ & ⋮ \\ {X}_{n - 1}^{2} & {X}_{n - 1} {Y}_{- 1 n} & {Y}_{n - 1}^{2} & {X}_{n - 1} & {Y}_{n - 1}\end{matrix} ]$$

Proceeding from M·C=Z, with

$$C = [ \begin{matrix}{C}_{0} \\ {C}_{1} \\ ⋮ \\ {C}_{5}\end{matrix} ] , \\ Z = [ \begin{matrix}1 \\ 1 \\ ⋮ \\ 1\end{matrix} ]$$

the vector C can be ascertained by the processor 510 according to

c=(M^{T}·M)⁻¹·M^{T}·Z

Z denotes the target amplitude of the calibration and represents a negative value of the parameter g. In this example implementation, the ellipse is mapped onto the unit circle.

According to the example implementation presented here, the ellipse parameters can then be determined from the components of the vector C as follows:

a=C₀, b=C₁/2, c=C₂, d=C₃/2, f=C₄/2, g=−1

Using the ellipse parameters thus obtained, the processor 510 is now able to calculate the characteristic data Aₓ, Oₓ, of the first error-afflicted periodic sensor signal X of the first sensor element 502, the characteristic data A_{y}, O_{y} of the second error-afflicted periodic sensor signal Y of the first sensor element 504, and the phase offset φ=φ_{y} between the first and second error-afflicted periodic sensor signal X′, Y′.

For the amplitude Aₓ of the first error-afflicted periodic sensor signal X, the ellipse equation can be rewritten as x=f(y) and the derivative can be set to be dx/dy=0. This can be used to obtain the y-position for the extremal value of x.

$$x = - \frac{d + b y ∓ \sqrt{( {b}^{2} {y}^{2} + 2 b d y + {d}^{2} - a c {y}^{2} - 2 afy - ag )}}{a}$$

Differentiating (dx/dy) and setting this derivative to zero allows the ascertainment of that Y-value at which this ellipse has its maxima and minima in relation to the X-value. In this case, the following expression is obtained for the y-position of the x-maxima and minima:

$${y}_{A x} = \frac{\pm b \sqrt{c ( g {b}^{2} - 2 b d f + c {d}^{2} + a {f}^{2} - a c g )} - b c d + a c f}{a {c}^{2} - c {b}^{2}}$$

y_{Ax}, thus denotes a y-value of the ellipse in the case of the maximum (minimum) x-value of the ellipse.

By inserting this y-position into the original ellipse equation, it is possible to obtain the maximum extent of the ellipse in the x-direction:

$${x}_{A x} = - \frac{d + b {y}_{A x}}{a} ∓ \sqrt{{( \frac{d + {by}_{Ax}}{a} )}^{2} - \frac{{cy}_{Ax}^{2} + 2 {fy}_{Ax} + g}{a}}$$

$$or$$

$${x}_{A x} = - \frac{d + b {y}_{A x} ∓ \sqrt{{b}^{2} {y}_{Ax}^{2} + 2 bd {y}_{A x} + {d}^{2} - {acy}_{Ax}^{2} - 2 {cfy}_{Ax} - ag}}{a}$$

x_{Ax} thus denotes maximum or minimum x-values of the ellipse corresponding to the ascertained ellipse parameters a, b, c, d, f, g.

For the amplitude A_{Y} of the second error-afflicted periodic sensor signal Y, the ellipse equation can be rewritten as y=f(x) and the derivative can be set to be dy/dx=0. This can be used to obtain the x-position for the extremal value of y.

$$y = - \frac{f + b x ∓ \sqrt{{b}^{2} {x}^{2} + 2 b f x + {f}^{2} - a c {x}^{2} - 2 c d x - c g}}{c}$$

Differentiating (dy/dx) and setting this derivative to zero allows the ascertainment of that X-value at which this ellipse has its maxima and minima in relation to the Y-value. In this case, the following expression is obtained for the x-position of the y-maxima and minima:

$${x}_{A y} = \frac{\pm b \sqrt{a ( g {b}^{2} - 2 b d f + c {d}^{2} + a {f}^{2} - a c g )} + a c d - a b f}{a {b}^{2} - c {a}^{2}}$$

x_{Ay} thus denotes an x-value of the ellipse in the case of the maximum (minimum) y-value of the ellipse.

By inserting this x-position into the original ellipse equation, it is possible to obtain the maximum extent of the ellipse in the y-direction:

$${x}_{Ay} = - \frac{f + b {y}_{Ay}}{a} ∓ \sqrt{{( \frac{f + {by}_{Ay}}{c} )}^{2} - \frac{{ax}_{Ay}^{2} + 2 {dy}_{Ay} + g}{c}}$$

$$or$$

$${x}_{Ay} = - \frac{f + b {y}_{Ay} ∓ \sqrt{{b}^{2} {y}_{Ay}^{2} + 2 bd {y}_{Ay} + {f}^{2} - {acx}_{Ay}^{2} - 2 {cdx}_{Ay} - cg}}{c}$$

y_{Ay} thus denotes maximum or minimum y-values of the ellipse corresponding to the ascertained ellipse parameters a, b, c, d, f, g.

The first mean value/offset O_{X} of the first error-afflicted periodic sensor signal can then be ascertained on the basis of an averaging of the maximum (x_{Ax+}) and minimum x-values

$$( {x}_{A x -} ) as per {O}_{X} = \frac{{x}_{A x +} + {x}_{A x -}}{2} = \frac{{x}_{A y +} + {x}_{A y -}}{2}$$

$${O}_{X} = \frac{c d - b f}{{b}^{2} - a c}$$

and the second mean value/offset O_{Y} of the second error-afflicted periodic sensor signal can be ascertained on the basis of an averaging of the maximum (y_{Ay+}) and minimum y-values

$$( {x}_{A y -} ) as per {O}_{Y} = \frac{{y}_{A y +} + {y}_{A y -}}{2} = \frac{{y}_{A x +} + {y}_{A x -}}{2}$$

$${O}_{Y} = \frac{a f - b d}{{b}^{2} - a c}$$

using the ellipse parameters a, b, c, d, f, g.

The amplitudes A_{X}, A_{Y} of the first and second error-afflicted periodic sensor signals can then each be ascertained on the basis of the extremal value ascertainment, for example on the basis of the maximum x-value (x_{Ax+}) and maximum y-value (y_{Ay+}) of the ellipse, and by taking account of the respective mean values O_{X}, O_{Y}.

A_{X}=X_{Ax+}−O_{X}

A_{Y}=Y_{Ay+}O_{Y}

The phase offset φ=φₓ−φ_{y} between first and second error-afflicted periodic sensor signal X, Y can be ascertained as per

$$ϕ = - asin ( \frac{{y}_{A x} - {O}_{Y}}{{A}_{Y}} )$$

where y_{Ax} denotes the y-value of the ellipse in the case of the maximum x-value, O_{Y} denotes the mean value of the second sensor signal, and A_{Y} denotes the amplitude of the second sensor signal.

The values A_{X}, A_{Y}, O_{X}, O_{Y} and cp obtained by the calibration can now be stored for application during a mode of operation (normal operation) of the angle sensor. To this end, a data memory may additionally be present in the apparatus 500.

During the operation of the angle sensor, the processor 510 can correct measurement values X, Y as follows:

$${X}^{′} = ( \frac{X - {O}_{X}}{{A}_{X}} )$$

$${Y}^{′} = ( \frac{Y - {O}_{Y}}{{A}_{Y}} )$$

$${Y}^{″} = \frac{{Y}^{′} + sin ϕ \cdot {X}^{′}}{cos ϕ}$$

$${X}^{″} = {X}^{′}$$

The values X″, Y″ then correspond to the corrected measurement values and the corrected angle α emerges as follows:

$$α = atan ( \frac{{Y}^{″}}{{X}^{″}} ) .$$

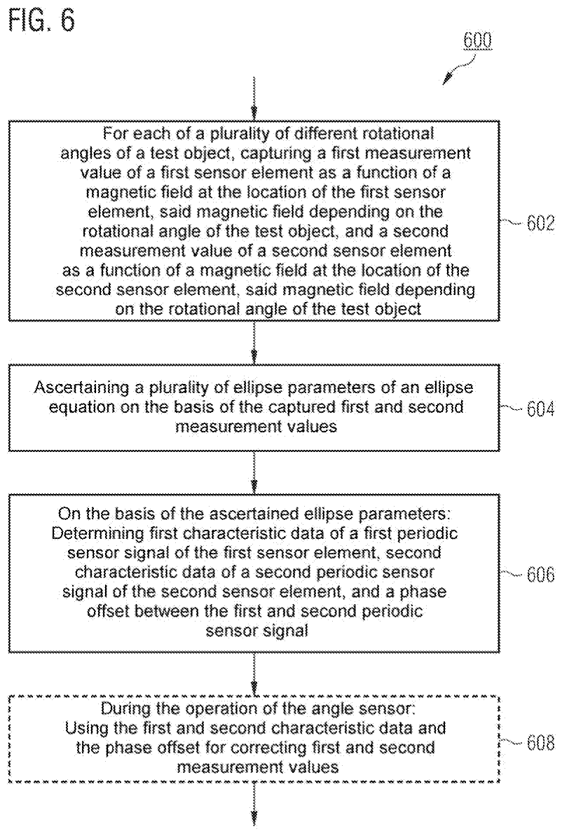

In summary, FIG. 6 illustrates a method 600 for calibrating an angle sensor.

The method 600 comprises, for each of a plurality of different rotational angles of a test object, capturing 602 a first measurement value of a first sensor element as a function of a magnetic field at the location of the first sensor element, the magnetic field depending on the rotational angle of the test object, and a second measurement value of a second sensor element as a function of a magnetic field at the location of the second sensor element, the magnetic field depending on the rotational angle of the test object. At 604, a plurality of ellipse parameters of an ellipse equation are ascertained on the basis of the captured first and second measurement values. At 606, there is a determination of first characteristic data of a first periodic sensor signal of the first sensor element and of second characteristic data of a second periodic sensor signal of the second sensor element, and of a phase offset between the first and second periodic sensor signal on the basis of the ascertained ellipse parameters.

In an optional process 608, the first and second characteristic data and the phase offset can be used to correct first and second measurement values and hence correct an estimated angle.

By way of example, example implementations of the present disclosure can be implemented in test equipment. Here, there is no need for an angle reference and hence no need for large and expensive optical encoders. Instead, a simply rotating homogeneous magnet can be used for an EoL test and/or EoL calibration. Relatively large rotating magnets can facilitate parallel testing for reducing the test costs.

Example implementations of the present disclosure can also be implemented in the sensor for use during operation. An autocalibration function can also be improved by the implementation of example implementations.

The aspects and features which are described together with one or more of the previously detailed examples and figures may also be combined with one or more of the other examples in order to replace an identical feature of the other example or in order to additionally introduce the feature in the other example.

Examples may furthermore be a computer program with program code for executing one or more of the above methods or may relate thereto when the computer program is executed on a computer or a processor. Steps, operations or processes of different methods described above may be executed by programmed computers or processors. Examples may also cover program storage apparatuses, e.g. digital data storage media, which are machine-readable, processor-readable or computer-readable, and code machine-executable, processor-executable or computer-executable programs of instructions. The instructions execute some or all of the steps of the above-described methods or bring about the execution thereof. The program storage apparatuses may comprise or be e.g. digital memories, magnetic storage media such as for example magnetic disks and magnetic tapes, hard disk drives or optically readable digital data storage media. Further examples may also cover computers, processors or control units that are programmed to execute the steps of the above-described methods, or (field) programmable logic arrays ((F)PLAs) or (field) programmable gate arrays ((F)PGAs) that are programmed to execute the steps of the above-described methods.

Only the principles of the disclosure are illustrated by the description and drawings. Furthermore, all examples mentioned here are expressly intended in principle to serve only for illustrative purposes, so as to support the reader in understanding the principles of the disclosure and the concepts provided by the inventor(s) for further refining the technology.

All statements made here relating to principles, aspects and examples of the disclosure and concrete examples thereof comprise the counterparts thereof.

A function block designated as “means for . . . ” executing a specific function may relate to a circuit designed to execute a specific function. Consequently a “means for something” may be implemented as a “means designed for or suitable for something”, e.g. a component or a circuit designed for or suitable for the respective task.

Functions of different elements shown in the figures including those function blocks designated as “means”, “means for providing a signal”, “means for generating a signal”, etc. may be implemented in the form of dedicated hardware, e.g. “a signal provider”, “a signal processing unit”, “a processor”, “a controller” etc., and as hardware capable of executing software in conjunction with associated software. When provided by a processor, the functions may be provided by a single dedicated processor, by a single jointly used processor or by a plurality of individual processors, some or all of which are able to be used jointly. However, the term “processor” or “controller” is far from being limited to hardware capable exclusively of executing software, but rather may encompass digital signal processor hardware (DSP hardware), network processor, application-specific integrated circuit (ASIC), field-programmable logic array (FPGA=Field Programmable Gate Array), read-only memory (ROM) for storing software, random access memory (RAM) and non-volatile storage device (storage). Other hardware, conventional and/or customized, may also be included.

A block diagram may illustrate for example a rough circuit diagram that implements the principles of the disclosure. In a similar manner, a flowchart, a flow diagram, a state transition diagram, a pseudo-code and the like may represent various processes, operations or steps that are represented for example substantially in a computer-readable medium and are thus executed by a computer or processor, regardless of whether such a computer or processor is explicitly shown. Methods disclosed in the description or in the patent claims may be implemented by a component having a means for executing each of the respective steps of these methods.

It is to be understood that the disclosure of a plurality of steps, processes, operations or functions disclosed in the description or the claims should not be interpreted as being in the specific order, unless this is explicitly or implicitly indicated otherwise, e.g. for technical reasons. The disclosure of a plurality of steps or functions therefore does not limit them to a specific order, unless these steps or functions are not interchangeable for technical reasons. Furthermore, in some examples, an individual step, function, process or operation may include a plurality of partial steps, functions, processes or operations and/or be subdivided into them. Such partial steps may be included and be part of the disclosure of this individual step, provided that they are not explicitly excluded.

Furthermore, the claims that follow are hereby incorporated in the detailed description, where each claim may be representative of a separate example by itself. While each claim may be representative of a separate example by itself, it should be taken into consideration that although a dependent claim may refer in the claims to a specific combination with one or more other claims other examples may also encompass a combination of the dependent claim with the subject matter of any other dependent or independent claim. Such combinations are explicitly proposed here, provided that no indication is given that a specific combination is not intended. Furthermore, features of a claim are also intended to be included for any other independent claim, even if this claim is not made directly dependent on the independent claim.

1. A method for calibrating an angle sensor, comprising:
capturing, for each of a plurality of different rotational angles of a test object, a first measurement value of a first sensor element as a function of a magnetic field at a location of the first sensor element, the magnetic field depending on a rotational angle of the test object,
capturing a second measurement value of a second sensor element as a function of a magnetic field at a location of the second sensor element, the magnetic field depending on the rotational angle of the test object;
ascertaining a plurality of ellipse parameters of an ellipse equation based on the first measurement value and the second measurement values for each of the plurality of different rotational angles; and
determining, based on the plurality of ellipse parameters, first characteristic data of a first periodic sensor signal of the first sensor element, second characteristic data of a second periodic sensor signal of the second sensor element, and a phase offset between the first and second periodic sensor signal.

2. The method as claimed in claim 1, wherein the first characteristic data and the second characteristic data are usable for correcting the angle in one mode of operation of the angle sensor.

3. The method as claimed in claim 1, wherein the first characteristic data comprise a first amplitude and a first mean value of the first periodic sensor signal and the second characteristic data comprise a second amplitude and a second mean value of the second periodic sensor signal.

4. The method as claimed in claim 1, wherein the different rotational angles, at which the first measurement value and the second measurement value, for each of the plurality of different rotational angles, are captured, capture at least one 360° rotation of the test object.

5. The method as claimed in claim 1, wherein the plurality of the first measurement value and second measurement value, for each of the plurality of different rotational angles, are respectively captured simultaneously.

6. The method as claimed in claim 1, wherein the first sensor element is sensitive to a first directional component of the magnetic field and the second sensor element is sensitive to a second directional component of the magnetic field, the second directional component being perpendicular to the first directional component.

7. The method as claimed in claim 1, wherein the first sensor element and the second sensor element are sensitive to a same directional component of the magnetic field, a 90° phase shift being set between the first sensor signal and the second sensor signal by way of at least one of a location of the first sensor element and the second sensor element or a distance between the first sensor element and the second sensor element.

8. The method as claimed in claim 1, wherein the first sensor element and the second sensor element each comprise at least one magnetic field sensor element.

9. The method as claimed in claim 1, wherein the plurality of ellipse parameters are ascertained based on a method of least squares.

10. The method as claimed in claim 1, wherein the ellipse equation has a form ax²+bxy+cy²+dx+fy+g=0 and ellipse parameters a, b, c, d, f, g, included in the plurality of ellipse parameters, are ascertained based on C=(M^{T}M)⁻¹M^{T}Z, where
$$M = [ \begin{matrix}{X}_{0}^{2} & {X}_{0} {Y}_{0} & {Y}_{0}^{2} & {X}_{0} & {Y}_{0} \\ {X}_{1}^{2} & {X}_{1} {Y}_{1} & {Y}_{1}^{2} & {X}_{1} & {Y}_{1} \\ ⋮ & ⋮ & ⋮ & ⋮ & ⋮ \\ {X}_{n - 1}^{2} & {X}_{n - 1} {Y}_{- 1 n} & {Y}_{n - 1}^{2} & {X}_{n - 1} & {Y}_{n - 1}\end{matrix} ]$$
is a measurement value matrix based on plurality of first measurement values, a plurality of second measurement values, and Z=[1 1 . . . 1]^{T}.

11. The method as claimed in claim 1, wherein the ellipse equation is rewritten as x=f(y) for the purposes of determining a first amplitude A_{X} and a first mean value O_{X} of the first periodic sensor signal and a derivative is set to be dx/dy=0 and wherein the ellipse equation is rewritten as y=f(x) for the purposes of determining a second amplitude A_{Y} and a second mean value O_{Y} of the second periodic sensor signal and the derivative is set to be dy/dx=0.

12. The method as claimed in claim 11, wherein the first mean value O_{X} is ascertained based on an averaging of maximum and minimum x-values of an ellipse corresponding to the plurality of ellipse parameters and the second mean value O_{Y} is ascertained based on an averaging of maximum and minimum y-values of the ellipse.

13. The method as claimed in claim 12, wherein the first amplitude A_{X} is ascertained based on a maximum x-value of the ellipse and the first mean value O_{X} and the second amplitude A_{Y} is ascertained based on a maximum y-value of the ellipse and the second mean value O_{Y}.

14. The method as claimed in claim 13, wherein the phase offset φ between the first periodic sensor signal and the second periodic sensor signal is ascertained as per
$$ϕ = - asin ( \frac{{y}_{A x} - {O}_{Y}}{{A}_{Y}} )$$
where y_{Ax} denotes a y-value of the ellipse in a case of the maximum x-value of the ellipse.

15. An apparatus for calibrating an angle sensor, comprising:
a data interface to capture, for each of a plurality of different rotational angles of a test object:
a first measurement value of a first sensor element as a function of a magnetic field at a location of the first sensor element, the magnetic field depending on the rotational angle of the test object, and
a second measurement value of a second sensor element as a function of a magnetic field at a location of the second sensor element, the magnetic field depending on the rotational angle of the test object; and
a processor to:
calculate a plurality of ellipse parameters of an ellipse equation based on the first measurement value and the second measurement value for each of the plurality of different rotational angles; and
calculate, based on the plurality of ellipse parameters, first characteristic data of a first periodic sensor signal of the first sensor element, second characteristic data of a second periodic sensor signal of the second sensor element, and a phase offset between the first and second periodic sensor signal.
